(19) United States
(12) Patent Application Publication
(10) Pub. No.: US 2013/0194562 A1
(43) Pub. Date: Aug. 1, 2013

(54) Lithographic Apparatus and Device Manufacturing Method

(71) Applicants: Hendrik Antony Johannes Neerhof, Eindhoven (NL); Markus Franciscus Antonius Eurlings, Tilburg (NL)

(72) Inventors: Hendrik Antony Johannes Neerhof, Eindhoven (NL); Markus Franciscus Antonius Eurlings, Tilburg (NL)

(73) Assignee: ASML Netherlands B.V., Veldhoven (NL)

(21) Appl. No.: 13/879,193

(22) PCT Filed: Sep. 13, 2011
(86) PCT No.: PCT/EP2011/065811

§ 371 Date: Apr. 12, 2013

Related U.S. Application Data
(60) Provisional application No. 61/393,155, filed on Oct. 14, 2010.

(51) Int. Cl. G03F 7/20

(52) U.S. Cl. CPC G03F 7/70133
USPC 355/71

(57) ABSTRACT

A lithographic apparatus comprising a source of EUV radiation, an illumination system configured to condition a radiation beam, and a projection system configured to project the radiation beam onto a substrate, wherein the apparatus further comprises a filter configured to prevent or reduce the transmission of unwanted radiation and an apparatus configured to detect damage of the filter, wherein the damage detection apparatus comprises an antenna configured to receive radio waves and an analysis apparatus configured to determine the presence of filter damage based upon the received radio waves.

### CROSS-REFERENCE TO RELATED APPLICATIONS

This application claims the benefit of U.S. provisional application 61/393,155, which was filed on Oct. 14, 2010 and which is incorporated herein in its entirety by reference.

### FIELD

The present invention relates to a lithographic apparatus and a method for manufacturing a device.

### BACKGROUND

A lithographic apparatus is a machine that applies a desired pattern onto a substrate, usually onto a target portion of the substrate. A lithographic apparatus can be used, for example, in the manufacture of integrated circuits (ICs). In that instance, a patterning device, which is alternatively referred to as a mask or a reticle, may be used to generate a circuit pattern to be formed on an individual layer of the IC. This pattern can be transferred onto a target portion (e.g., comprising part of, one, or several dies) on a substrate (e.g., a silicon wafer). Transfer of the pattern is typically via imaging onto a layer of radiation-sensitive material (resist) provided on the substrate. In general, a single substrate will contain a network of adjacent target portions that are successively patterned.

Lithography is widely recognized as one of the key steps in the manufacture of ICs and other devices and/or structures. However, as the dimensions of features made using lithography become smaller, lithography is becoming a more critical factor for enabling miniature IC or other devices and/or structures to be manufactured.

A theoretical estimate of the limits of pattern printing can be given by the Rayleigh criterion for resolution as shown in equation (1):

$$CD = {k}_{1} * \frac{λ}{NA} \qquad ( 1 )$$

where A is the wavelength of the radiation used, NA is the numerical aperture of the projection system used to print the pattern, k₁ is a process dependent adjustment factor, also called the Rayleigh constant, and CD is the feature size (or critical dimension) of the printed feature. It follows from equation (1) that reduction of the minimum printable size of features can be obtained in three ways: by shortening the exposure wavelength A, by increasing the numerical aperture NA or by decreasing the value of k₁.

In order to shorten the exposure wavelength and, thus, reduce the minimum printable size, it has been proposed to use an extreme ultraviolet (EUV) radiation source. EUV radiation is electromagnetic radiation having a wavelength within the range of 5-20 nm, for example within the range of 13-14 nm, or example within the range of 5-10 nm such as 6.7 nm or 6.8 nm. Possible sources include, for example, laser-produced plasma sources, discharge plasma sources, or sources based on synchrotron radiation provided by an electron storage ring.

EUV lithographic apparatus use mirrors to condition and direct EUV radiation. These mirrors may be susceptible to damage due to radiation outside of the EUV spectrum being absorbed by the mirrors rather than reflected. A filter may be used to remove radiation from outside of the EUV spectrum before it is incident upon the mirrors.

### SUMMARY

It is desirable to reduce the risk that a mirror of an EUV lithographic apparatus will be damaged by radiation which falls outside of the EUV spectrum.

According to a first embodiment of the present invention, there is provided a lithographic apparatus comprising a source of EUV radiation, an illumination system configured to condition a radiation beam, and a projection system configured to project the radiation beam onto a substrate. The apparatus further comprises a filter configured to prevent or reduce the transmission of unwanted radiation and an apparatus configured to detect damage of the filter. The filter damage detection apparatus comprises an antenna configured to receive radio waves and an analysis apparatus configured to determine the presence of filter damage based upon the received radio waves.

According to a second embodiment of the present invention there is provided a filter damage detection apparatus comprising an antenna configured to receive radio waves and an analysis apparatus configured to determine the presence of filter damage based upon the received radio waves.

According to a third embodiment of the present invention there is provided a method of monitoring for damage of a filter in a lithographic apparatus comprising receiving radio waves using an antenna and determining the presence of filter damage based upon the received radio waves.

Further features and advantages of the present invention, as well as the structure and operation of various embodiments of the present invention, are described in detail below with reference to the accompanying drawings. It is noted that the present invention is not limited to the specific embodiments described herein. Such embodiments are presented herein for illustrative purposes only. Additional embodiments will be apparent to persons skilled in the relevant art(s) based on the teachings contained herein.

### BRIEF DESCRIPTION OF THE DRAWINGS/FIGURES

The accompanying drawings, which are incorporated herein and form part of the specification, illustrate the present invention and, together with the description, further serve to explain the principles of the present invention and to enable a person skilled in the relevant art(s) to make and use the present invention.

FIG. 1 schematically depicts a lithographic apparatus, according to an embodiment of the present invention.

FIG. 2 schematically depicts the lithographic apparatus, in more detail, including a laser produced plasma (LPP) source collector module SO.

FIG. 3 schematically depicts a filter damage detection apparatus, according to an embodiment of the present invention, with an undamaged filter.

FIG. 4 schematically depicts the filter damage detection apparatus of FIG. 3 with a damaged filter.

FIG. 5 is a graph which shows transmission of radio waves by holes of different sizes over a range of frequencies.

The features and advantages of the present invention will become more apparent from the detailed description set forth below when taken in conjunction with the drawings, in which like reference characters identify corresponding elements throughout. In the drawings, like reference numbers generally indicate identical, functionally similar, and/or structurally similar elements. The drawing in which an element first appears is indicated by the leftmost digit(s) in the corresponding reference number.

### DETAILED DESCRIPTION

This specification discloses one or more embodiments that incorporate the features of this present invention. The disclosed embodiment(s) merely exemplify the present invention. The scope of the present invention is not limited to the disclosed embodiment(s). The present invention is defined by the claims appended hereto.

The embodiment(s) described, and references in the specification to “one embodiment”, “an embodiment”, “an example embodiment”, etc., indicate that the embodiment(s) described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is understood that it is within the knowledge of one skilled in the art to effect such feature, structure, or characteristic in connection with other embodiments whether or not explicitly described.

Embodiments of the present invention may be implemented in hardware, firmware, software, or any combination thereof. Embodiments of the present invention may also be implemented as instructions stored on a machine-readable medium, which may be read and executed by one or more processors. A machine-readable medium may include any mechanism for storing or transmitting information in a form readable by a machine (e.g., a computing device). For example, a machine-readable medium may include read only memory (ROM); random access memory (RAM); magnetic disk storage media; optical storage media; flash memory devices; electrical, optical, acoustical or other forms of propagated signals (e.g., carrier waves, infrared signals, digital signals, etc.), and others. Further, firmware, software, routines, instructions may be described herein as performing certain actions. However, it should be appreciated that such descriptions are merely for convenience and that such actions in fact result from computing devices, processors, controllers, or other devices executing the firmware, software, routines, instructions, etc.

Before describing such embodiments in more detail, however, it is instructive to present an example environment in which embodiments of the present invention may be implemented.

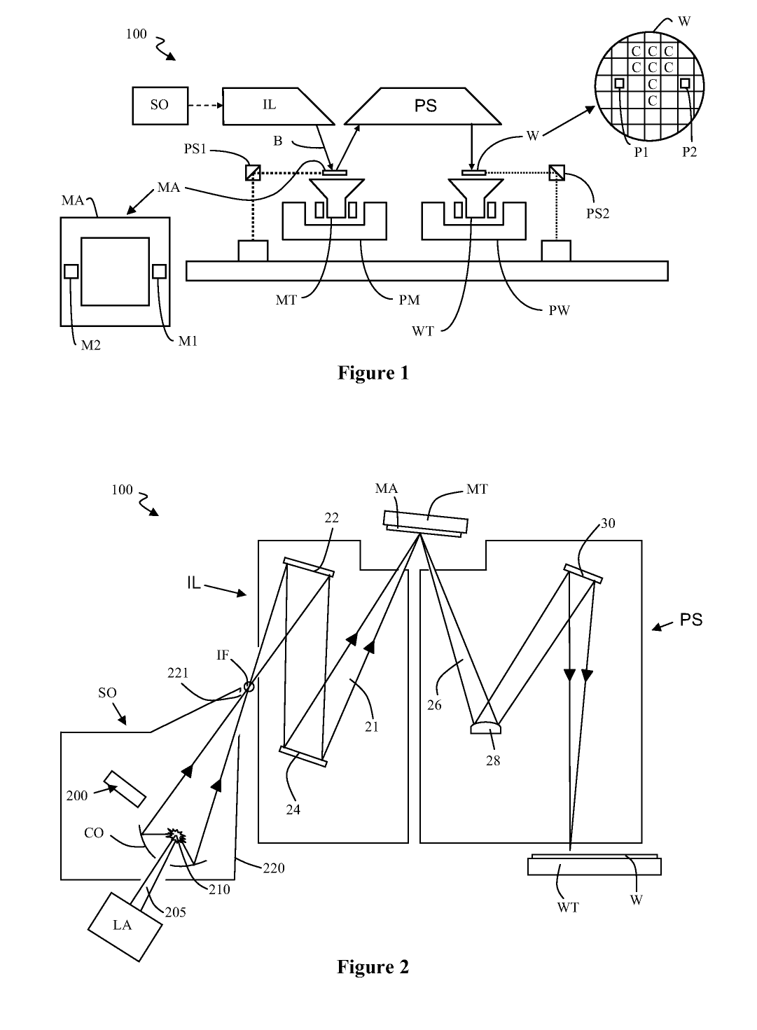

FIG. 1 schematically depicts a lithographic apparatus 100 including a source collector module SO according to one embodiment of the present invention. The apparatus comprises an illumination system (illuminator) IL configured to condition a radiation beam B (e.g., EUV radiation), a support structure (e.g., a mask table) MT constructed to support a patterning device (e.g., a mask or a reticle) MA and connected to a first positioner PM configured to accurately position the patterning device, a substrate table (e.g., a wafer table) WT constructed to hold a substrate (e.g., a resist-coated wafer) W and connected to a second positioner PW configured to accurately position the substrate, and a projection system (e.g., a reflective projection system) PS configured to project a pattern imparted to the radiation beam B by patterning device MA onto a target portion C (e.g., comprising one or more dies) of the substrate W.

The illumination system may include various types of optical components, such as refractive, reflective, magnetic, electromagnetic, electrostatic or other types of optical components, or any combination thereof, for directing, shaping, or controlling radiation.

The support structure MT holds the patterning device MA in a manner that depends on the orientation of the patterning device, the design of the lithographic apparatus, and other conditions, such as for example whether or not the patterning device is held in a vacuum environment. The support structure can use mechanical, vacuum, electrostatic or other clamping techniques to hold the patterning device. The support structure may be a frame or a table, for example, which may be fixed or movable as required. The support structure may ensure that the patterning device is at a desired position, for example with respect to the projection system.

The term “patterning device” should be broadly interpreted as referring to any device that can be used to impart a radiation beam with a pattern in its cross-section such as to create a pattern in a target portion of the substrate. The pattern imparted to the radiation beam may correspond to a particular functional layer in a device being created in the target portion, such as an integrated circuit.

The patterning device may be transmissive or reflective. Examples of patterning devices include masks, programmable mirror arrays, and programmable LCD panels. Masks are well known in lithography, and include mask types such as binary, alternating phase-shift, and attenuated phase-shift, as well as various hybrid mask types. An example of a programmable mirror array employs a matrix arrangement of small mirrors, each of which can be individually tilted so as to reflect an incoming radiation beam in different directions. The tilted mirrors impart a pattern in a radiation beam which is reflected by the mirror matrix.

The projection system, like the illumination system, may include various types of optical components, such as refractive, reflective, magnetic, electromagnetic, electrostatic or other types of optical components, or any combination thereof, as appropriate for the exposure radiation being used, or for other factors such as the use of a vacuum. It may be desired to use a vacuum for EUV radiation since other gases may absorb too much radiation. A vacuum environment may therefore be provided to the whole beam path with the aid of a vacuum wall and vacuum pumps.

As here depicted, the apparatus is of a reflective type (e.g., employing a reflective mask).

The lithographic apparatus may be of a type having two (dual stage) or more substrate tables (and/or two or more mask tables). In such “multiple stage” machines the additional tables may be used in parallel, or preparatory steps may be carried out on one or more tables while one or more other tables are being used for exposure.

Referring to FIG. 1, the illuminator IL receives an extreme ultra violet (EUV) radiation beam from the source collector module SO. Methods to produce EUV light include, but are not necessarily limited to, converting a material into a plasma state that has at least one element, e.g., xenon, lithium or tin, with one or more emission lines in the EUV range. In one such method, often termed laser produced plasma (“LPP”) the required plasma can be produced by irradiating a fuel, such as a droplet, stream or cluster of material having the required line-emitting element, with a laser beam. The source collector module SO may be part of an EUV radiation system including a laser, not shown in FIG. 1, for providing the laser beam exciting the fuel. The resulting plasma emits output radiation, e.g., EUV radiation, which is collected using a radiation collector, disposed in the source collector module. The laser and the source collector module may be separate entities, for example when a CO₂ laser is used to provide the laser beam for fuel excitation.

In such cases, the laser is not considered to form part of the lithographic apparatus and the radiation beam is passed from the laser to the source collector module with the aid of a beam delivery system comprising, for example, suitable directing mirrors and/or a beam expander. In other cases the source may be an integral part of the source collector module, for example when the source is a discharge produced plasma EUV generator, often termed as a DPP source.

The illuminator IL may comprise an adjuster for adjusting the angular intensity distribution of the radiation beam. Generally, at least the outer and/or inner radial extent (commonly referred to as σ-outer and σ-inner, respectively) of the intensity distribution in a pupil plane of the illuminator can be adjusted. In addition, the illuminator IL may comprise various other components, such as faceted field and pupil mirror devices. The illuminator may be used to condition the radiation beam, to have a desired uniformity and intensity distribution in its cross-section.

The radiation beam B is incident on the patterning device (e.g., mask) MA, which is held on the support structure (e.g., mask table) MT, and is patterned by the patterning device. After being reflected from the patterning device (e.g., mask) MA, the radiation beam B passes through the projection system PS, which focuses the beam onto a target portion C of the substrate W. With the aid of the second positioner PW and position sensor PS2 (e.g., an interferometric device, linear encoder or capacitive sensor), the substrate table WT can be moved accurately, e.g., so as to position different target portions C in the path of the radiation beam B. Similarly, the first positioner PM and another position sensor PS1 can be used to accurately position the patterning device (e.g., mask) MA with respect to the path of the radiation beam B. Patterning device (e.g., mask) MA and substrate W may be aligned using mask alignment marks M1, M2 and substrate alignment marks P1, P2.

The depicted apparatus could be used in at least one of the following modes:

1. In step mode, the support structure (e.g., mask table) MT and the substrate table WT are kept essentially stationary, while an entire pattern imparted to the radiation beam is projected onto a target portion C at one time (i.e., a single static exposure). The substrate table WT is then shifted in the X and/or Y direction so that a different target portion C can be exposed.

2. In scan mode, the support structure (e.g., mask table) MT and the substrate table WT are scanned synchronously while a pattern imparted to the radiation beam is projected onto a target portion C (i.e., a single dynamic exposure). The velocity and direction of the substrate table WT relative to the support structure (e.g., mask table) MT may be determined by the (de-)magnification and image reversal characteristics of the projection system PS.

3. In another mode, the support structure (e.g., mask table) MT is kept essentially stationary holding a programmable patterning device, and the substrate table WT is moved or scanned while a pattern imparted to the radiation beam is projected onto a target portion C. In this mode, generally a pulsed radiation source is employed and the programmable patterning device is updated as required after each movement of the substrate table WT or in between successive radiation pulses during a scan. This mode of operation can be readily applied to maskless lithography that utilizes programmable patterning device, such as a programmable mirror array of a type as referred to above.

Combinations and/or variations on the above described modes of use or entirely different modes of use may also be employed.

FIG. 2 shows the apparatus 100 in more detail, including the source collector module SO, the illumination system IL, and the projection system PS. The source collector module SO is constructed and arranged such that a vacuum environment can be maintained in an enclosing structure 220 of the source collector module SO.

A laser LA is arranged to deposit laser energy via a laser beam 205 into a fuel, such as xenon (Xe), tin (Sn) or lithium (Li) which is provided from a fuel supply 200, thereby creating a highly ionized plasma 210 with electron temperatures of several 10's of eV. The energetic radiation generated during de-excitation and recombination of these ions is emitted from the plasma, collected and focused by a near normal incidence collector optic CO.

Radiation that is reflected by the collector optic CO is focused in a virtual source point IF. The virtual source point IF is commonly referred to as the intermediate focus, and the source collector module SO is arranged such that the intermediate focus IF is located at or near an opening 221 in the enclosing structure 220. The virtual source point IF is an image of the radiation emitting plasma 210.

Subsequently the radiation traverses the illumination system IL. The illumination system IL may include a faceted field mirror device 22 and a faceted pupil mirror device 24 arranged to provide a desired angular distribution of the radiation beam 21 at the patterning device MA, as well as a desired uniformity of radiation intensity at the patterning device MA. Upon reflection of the beam of radiation 21 at the patterning device MA, a patterned beam 26 is formed and the patterned beam 26 is imaged by the projection system PS via reflective elements 28, 30 onto a substrate W held by the substrate table WT.

More elements than shown may generally be present in the illumination system IL and projection system PS. Further, there may be more mirrors present than those shown in the Figures, for example there may be 1-6 additional reflective elements present in the projection system PS than shown in FIG. 2.

A transmissive optical filter may be present in the lithographic apparatus, the transmissive optical filter being transmissive for EUV radiation and less transmissive for radiation at other wavelengths (e.g., substantially absorbing or reflecting of radiation at other wavelengths). The transmissive optical filter may for example be a filter which is configured to absorb or reflect infrared (IR) radiation, i.e., configured to prevent or reduce the transmission of infrared radiation, and is referred to hereafter as an IR filter.

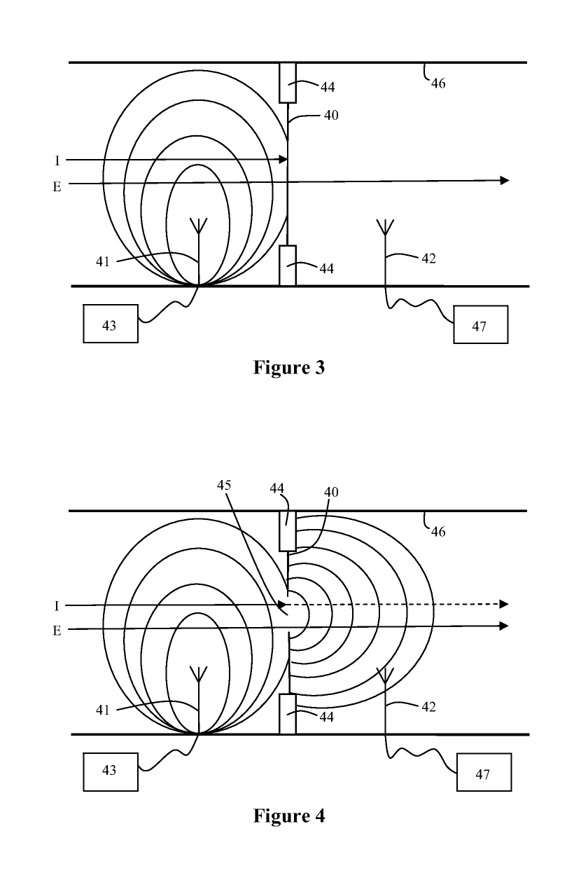

FIG. 3 schematically shows part of the lithographic apparatus within which an IR filter 40 has been provided. The IR filter 40 may for example be located in the source collector module CO or the illumination system IL of the lithographic apparatus (for example before the first mirror 22 of the illumination system). The IR filter 40 may for example comprise a grid that defines holes which are dimensioned such that they transmit EUV radiation and do not transmit IR radiation. Alternatively, the IR filter 40 may for example comprise a zirconium-silicon foil which does not transmit IR radiation. The IR filter 40 may for example block IR radiation which is produced by the plasma 210 (see FIG. 2), and may also block a laser beam which is used to generate the plasma in an LPP radiation system (the laser beam may be an IR laser beam).

The IR filter 40 may be susceptible to damage. For example a hole may appear in the IR filter 40. If this were to occur, then IR radiation could damage mirrors 22, 24 of the illumination system IL and could damage other optical components of the lithographic apparatus. For this reason it is desirable to be able to detect the presence of a hole in the IR filter 40.

FIG. 3 schematically shows a filter damage detection apparatus configured to detect damage of the filter which comprises a transmitter 41 which is configured to emit radio waves and an antenna 42 which is configured to receive radio waves. The transmitter 41 is connected to a controller 43. The controller 43 is configured to send a signal to the transmitter 41 for transmission by the transmitter. The controller 43 may be configured to send a signal to the transmitter 41 for transmission which comprises a plurality of frequencies. The antenna 42 is connected to an analysis apparatus 47 which is configured to determine the presence of damage to the IR filter 40 based upon radio waves received by the antenna.

EUV radiation is shown schematically in FIG. 3 as arrow E which travels through the IR filter. IR radiation is shown schematically in FIG. 3 as arrow I which is blocked by the IR filter.

A support structure 44 holds the IR filter 40. The support structure 44 and the IR filter 40 together form a barrier which substantially prevents the passage of radio waves or considerably attenuates the radio waves. The support structure 44 and the IR filter 40 thereby prevent radio waves emitted by the transmitter 41 from reaching the antenna 42 (or considerably reduces the power of radio waves incident at the antenna).

The transmitter 41 may for example comprise a piece of wire. The piece of wire may for example have a length which corresponds to one quarter of the wavelength of the radio waves transmitted by the transmitter (or may have some other suitable length). The length of the transmitter 41 may for example be between 1 cm and 1 m (or may be some other length). The antenna 42 may for example comprise a piece of wire, and may have the same length or a similar length as the transmitter (or may have some other suitable length). Although the transmitter 41 and antenna 42 are shown as being transverse to the direction of propagation of the EUV radiation, they may have any other suitable orientation. The transmitter 41 and/or antenna 42 may comprise a length of metal instead of a piece of wire

The radio waves transmitted by the transmitter are not transmitted in the form of a beam, but instead are transmitted in all directions (or substantially all directions). This is represented schematically by oval lines which emanate from the transmitter. Similarly, the antenna 42 may be capable of receiving radio waves from all directions (or substantially all directions).

FIG. 4 shows the same components as FIG. 3, but with a hole 45 being present in the IR filter 40. The hole 45 allows the transmission of some IR radiation, as shown by the continuation of arrow I as a dotted line. The transmitted IR radiation may cause damage to mirrors or other optical components of the lithographic apparatus. For this reason it is desirable to detect the presence of the hole 45. As is shown schematically in FIG. 4, radio waves emitted by the transmitter 41 pass through the hole 45. The radio waves are represented by curved lines which emanate from the hole 45. The radio waves are received by the antenna 42.

Detection of the radio waves at the antenna 42 indicates the presence of the hole 45 in the IR filter 40. When the analysis apparatus 47 receives a signal from the antenna 42 indicating the presence of the radio waves, the analysis apparatus 47 may cause a procedure to be initiated which is intended to prevent or limit damage to mirrors or other optical components of the lithographic apparatus. The procedure may for example comprise switching off the laser LA (see FIG. 2), blocking the laser beam, preventing the generation of EUV (and IR) radiation in some other way, blocking EUV and IR radiation, or diverting EUV and IR radiation. The procedure may be executed sufficiently quickly that damage of the mirrors or other optical components of the lithographic apparatus is avoided.

As mentioned further above, the IR filter 40 may comprise a grid which defines holes that are dimensioned such that they transmit EUV radiation and do not transmit IR radiation. The holes may for example measure 5 microns across. It may be desirable to detect the presence of a hole which has a diameter of around 1 mm, since a hole of this size may transmit a sufficiently high intensity of IR that damage may be caused to mirrors or other optical elements of the lithographic apparatus.

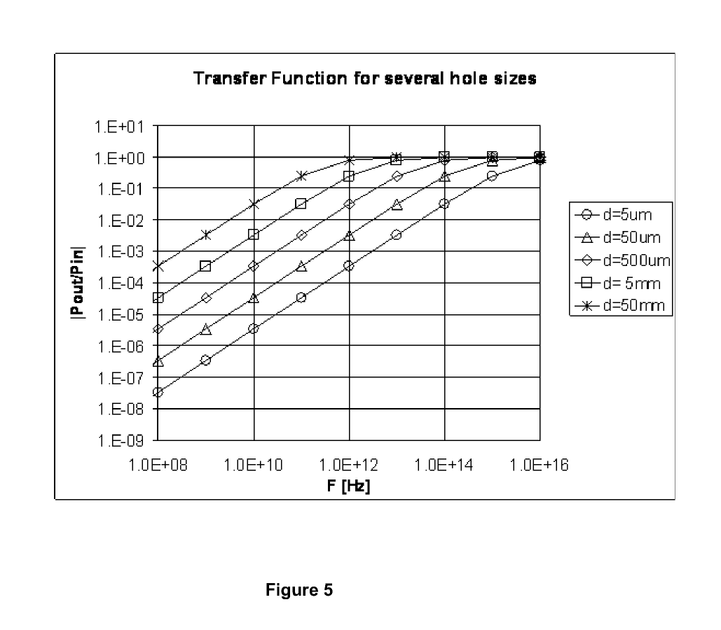

FIG. 5 is a graph which shows how the power of radio waves received at the antenna varies as a function of the frequency of the radio waves. The data shown in FIG. 5 was obtained using a simulation, and includes the results of that simulation for holes measuring between 5 microns and 50 mm across. It can be seen that for all frequencies of radio waves some radiation is received at the antenna but the power of the radiation increases as the size of the hole increases. This allows, for example, a hole which measures 50 mm across to be distinguished from a hole which measures 5 microns across. As the frequency of the radio waves is increased, the amount of power received at the antenna increases. However, when the frequency of the radio waves reaches around 1000 GHz the power received at the antenna reaches a maximum (a normalized value of 1) for larger hole sizes. As a result it may no longer be possible to distinguish between a 50 mm hole and a 5 mm hole. Further increases of the frequency cause the power at the antenna to reach the maximum for progressively smaller holes, thereby reducing the capacity of the apparatus to distinguish between holes of different sizes.

The radio waves transmitted by the transmitter 41 may have a frequency which is selected to allow holes having a range of different sizes to be detected. The frequency may be high enough that a sufficiently high power of radio waves is received at the antenna to allow detection, but may be low enough that different hole sizes give rise to different detected powers at the antenna (for a range of hole sizes that is to be detected). Referring to FIG. 5, for example, it may be desirable to use radio waves having a frequency of around 100 GHz, since this will provide relatively high powers at the antenna and allows holes having sizes in the range 5 microns to 50 mm to be distinguished. In an embodiment, the radio waves may for example have a frequency in the range 30 GHz to 300 GHz, more preferably 80 GHz to 120 GHz. Such frequency may have the advantage that the radiation can be better pointed towards the grid, thus there may be less leakage through gaps aside from the grid.

The radio waves may for example have a frequency which is less than 1000 GHz, more preferably less than 300 GHz, even more preferably less than 150 GHz, or less than 10 GHz. The radio waves may have a frequency which is greater than 100 KHz, or greater than 1 MHz, or greater than 10 MHz, or greater than 100 MHz. Any combination of the above lower and upper frequency limits are encompassed herein, wherein the broadest range formed is from 100 KHz to 1000 GHz.

The radio waves may for example lie in the Extremely High Frequency radio band (30-300 GHz), the Super High Frequency radio band (3-30 GHz), the Ultra High Frequency radio band (300 MHz-3 GHz), the Very High Frequency radio band (30-300 MHz), the High Frequency radio band (3-30 MHz), the Medium Frequency radio band (300 KHz-3 MHz), or the Low Frequency radio band (30-300 KHz).

As may be seen from FIG. 5, radio waves will be partially transmitted by a hole which measures 5 microns across (i.e., transmitted with a significantly attenuated power). If the IR filter 40 is formed from a grid which defines holes that measure 5 microns across, then some radio waves will be received by the antenna 42 when the IR filter 40 is not damaged. The radio waves which are received by the antenna 42 when the IR filter 40 is not damaged may be recorded as a background level of radio waves by the analysis apparatus 47. A significant increase of the power of the received radio waves above this background level may be interpreted by the analysis apparatus 47 as indicating that the IR filter 40 has been damaged (i.e., that a hole which is significantly bigger than 5 microns across has appeared in the IR filter).

Some radio waves may be transmitted by an IR filter comprising a grid which defines holes having a different size (i.e., greater than 5 microns across or less than 5 microns across). Where this is the case the above approach may still be applied, with radio waves detected when the IR filter is undamaged being recorded as a background level, and a significant increase of the power of the radio waves being interpreted as indicating damage to the IR filter.

As mentioned further above, the IR filter 40 may comprise a zirconium-silicon foil (or may comprise some other foil). Where this is the case the IR filter may, together with the support structure 44, block all radio waves. In this context the level of background radio waves may be very low or may be zero.

In an embodiment, the transmitter 41 may transmit radio waves having a single frequency. Alternatively, the frequency of the radio waves may vary, for example with the radio waves sweeping between a lower frequency and a higher frequency (or between a higher frequency and a lower frequency). In an embodiment, a modulation may be applied to the radio waves transmitted by the transmitter 41. Varying the frequency of the transmitted radio waves, or applying a modulation to the radio waves, may improve discrimination between received radio waves that were transmitted by the transmitter 41 and radio waves which were generated by other components of the lithographic apparatus.

Although only one antenna 42 is shown in FIGS. 3 and 4, more than one antenna may be provided (e.g., 2, 3, 4 or more antennas). Where this is the case, the phase of the radio waves detected by the antennas may be monitored by the analysis apparatus 47 (for example using quadrature detection). If phase information is monitored by the analysis apparatus 47 then it may be used to determine the location of a hole 45 in the IR filter 40. This is because the path length from the hole to each antenna will depend upon the location of the hole.

Phase information may also be used to distinguish radio waves which have passed through a hole 45 in the IR filter 40 from radio waves which have travelled via some other route (using path length information derived from the phase information).

The transmitter 41 and antenna 42 may be positioned such that they do not intersect with EUV radiation which is used to project patterns onto a substrate. Where this is done, the transmitter 41 and antenna 42 do not cause a reduction of the intensity of the EUV radiation, and do not introduce a shadow into the EUV radiation.

The source collector module SO (see FIG. 2) may generate EUV radiation and associated IR radiation in a pulsed manner. The control electronics 43 may be configured such that the transmitter 41 transmits radio waves when EUV radiation is not being emitted by the source collector module SO. This may reduce the amount of background radiation present in the lithographic apparatus when detection of damage to the IR filter 40 is being performed.

In FIGS. 3 and 4 the transmitter 41 is shown as being on the same side of the IR filter 40 as the EUV plasma 210, with the antenna 42 being on an opposite side of the IR filter. In an embodiment, the antenna may be on the same side of the IR filter as the EUV plasma, with the transmitter being on an opposite side of the IR filter. Where this is done, the antenna may receive a greater amount of background radio waves, for example radio waves generated by the EUV plasma. For this reason, detection of damage of the IR filter may be performed when EUV radiation is not being emitted by the source collector module SO (i.e., between pulses of EUV radiation).

It is not necessary for the transmitter and/or antenna to positioned such that they have a direct line of sight to a hole 45 in the IR filter, since propagation of the radio waves is not in the form of a beam but instead is multidirectional. In some instances, some screening of a transmitter and/or an antenna may occur (e.g., if an antenna is located immediately behind a component of the lithographic apparatus). A plurality of transmitters and/or antennas may be provided, for example in order to reduce the effect of the screening.

In the above described embodiments of the present invention the support structure 44 acts as a blocking structure which blocks radio waves which could otherwise pass around edges of the IR filter 40. The support structure 44 may for example comprise a metal sheet which extends inwardly from walls 46 of the lithographic apparatus. The support structure 44 may include a grid or grids. The holes of the grid or grids may for example have the same size or a smaller size than the holes defined by the grid of the IR filter 40. In an embodiment, a blocking structure may be provided which does not form part of a support structure. In an embodiment a blocking structure may be provided which is partially formed from the support structure and partially formed from a non-supporting structure.

In this context blocking of the radio waves is not intended to mean that no radio waves are transmitted, and may for example mean that a small proportion of radio waves are transmitted (the amount proportion radio waves being sufficiently small that it does not prevent detection of damage to the IR filter in the manner described above). In an embodiment, one or more gaps may be present between the IR filter 40 the support structure 44 and the walls 46 of the lithographic apparatus. The analysis apparatus 47 may take into account the presence of radio waves which pass through the one or more gaps, for example by identifying this as background radio waves which do not indicate the presence of a hole in the IR filter.

The analysis apparatus 47 may take into account background levels of radio waves which may be present when there is no hole in the IR filter 40.

The walls 46 of the lithographic apparatus may act as a Faraday cage which prevents or substantially prevents radio waves outside of the lithographic apparatus from entering into the lithographic apparatus in the vicinity of the antenna 42.

As mentioned above, the transmitter 41 and antenna 42 may be made from wire. The wire may be made from a metal which provides low out-gassing and which therefore does not have a significantly detrimental effect upon a vacuum provided in the lithographic apparatus. The controller 43 and the analysis apparatus 47 may be located outside of the vacuum portion of the lithographic apparatus, and therefore may be constructed from materials which give rise to significant amounts of out-gassing without contaminating the vacuum in the lithographic apparatus. In an alternative arrangement, the controller 43 and/or the analysis apparatus 47 may be sealed in a box which may be located in the vacuum portion of the lithographic apparatus. The box may be formed from a material having a low outgassing coefficient.

In an embodiment, the transmitter 41 may be omitted from the apparatus. Where this is done, the EUV emitting plasma 210 (see FIG. 2) may act as a source of the radio waves (the plasma emits radiation over a very wide range of frequencies). The antenna 42 and the analysis apparatus 47 may operate in the same manner as described above, i.e., monitoring for radio waves which are transmitted by the IR filter 40 if a hole 45 is present in the IR filter.

Although the above description relates to detecting damage to an IR filter 40, the damage detection apparatus may be used to detect damage in other filters.

Although specific reference may be made in this text to the use of lithographic apparatus in the manufacture of ICs, it should be understood that the lithographic apparatus described herein may have other applications, such as the manufacture of integrated optical systems, guidance and detection patterns for magnetic domain memories, flat-panel displays, liquid-crystal displays (LCDs), thin-film magnetic heads, etc. The skilled artisan will appreciate that, in the context of such alternative applications, any use of the terms “wafer” or “die” herein may be considered as synonymous with the more general terms “substrate” or “target portion”, respectively. The substrate referred to herein may be processed, before or after exposure, in for example a track (a tool that typically applies a layer of resist to a substrate and develops the exposed resist), a metrology tool and/or an inspection tool. Where applicable, the disclosure herein may be applied to such and other substrate processing tools. Further, the substrate may be processed more than once, for example in order to create a multi-layer IC, so that the term substrate used herein may also refer to a substrate that already contains multiple processed layers.

The term “lens”, where the context allows, may refer to any one or combination of various types of optical components, including refractive, reflective, magnetic, electromagnetic and electrostatic optical components.

The term “EUV radiation” may be considered to encompass electromagnetic radiation having a wavelength within the range of 5-20 nm, for example within the range of 13-14 nm, or example within the range of 5-10 nm such as 6.7 nm or 6.8 nm.

Although embodiments of the present invention have been described in terms of an EUV lithographic apparatus in which the EUV radiation is generated by an LPP source, the present invention may be used in an EUV lithographic apparatus in which the EUV radiation is generated by a DPP source.

While specific embodiments of the present invention have been described above, it will be appreciated that the present invention may be practiced otherwise than as described. For example, the present invention may take the form of a computer program containing one or more sequences of machine-readable instructions describing a method as disclosed above, or a data storage medium (e.g., semiconductor memory, magnetic or optical disk) having such a computer program stored therein. The descriptions above are intended to be illustrative, not limiting. Thus it will be apparent to one skilled in the art that modifications may be made to the present invention as described without departing from the scope of the claims set out below.

It is to be appreciated that the Detailed Description section, and not the Summary and Abstract sections, is intended to be used to interpret the claims. The Summary and Abstract sections may set forth one or more but not all exemplary embodiments of the present invention as contemplated by the inventor(s), and thus, are not intended to limit the present invention and the appended claims in any way.

The present invention has been described above with the aid of functional building blocks illustrating the implementation of specified functions and relationships thereof. The boundaries of these functional building blocks have been arbitrarily defined herein for the convenience of the description. Alternate boundaries can be defined so long as the specified functions and relationships thereof are appropriately performed.

The foregoing description of the specific embodiments will so fully reveal the general nature of the present invention that others can, by applying knowledge within the skill of the art, readily modify and/or adapt for various applications such specific embodiments, without undue experimentation, without departing from the general concept of the present invention. Therefore, such adaptations and modifications are intended to be within the meaning and range of equivalents of the disclosed embodiments, based on the teaching and guidance presented herein. It is to be understood that the phraseology or terminology herein is for the purpose of description and not of limitation, such that the terminology or phraseology of the present specification is to be interpreted by the skilled artisan in light of the teachings and guidance.

The breadth and scope of the present invention should not be limited by any of the above-described exemplary embodiments, but should be defined only in accordance with the following claims and their equivalents.

1. A lithographic apparatus, comprising:
a source of EUV radiation;
an illumination system configured to condition a radiation beam;
a projection system configured to project the radiation beam onto a substrate;
a filter configured to prevent or reduce the transmission of unwanted radiation;
an apparatus configured to detect damage of the filter, wherein the filter damage detection apparatus comprises an antenna configured to receive radio waves; and
an analysis apparatus configured to determine the presence of filter damage based upon the received radio waves.

2. The lithographic apparatus of claim 1, wherein the damage detection apparatus further comprises a transmitter located on an opposite side of the filter from the antenna, the transmitter being connected to a controller and being configured to transmit radio waves.

3. The lithographic apparatus of claim 2, wherein the transmitter is located on a side of the filter which is nearest to the source of EUV radiation.

4. The lithographic apparatus of claim 2, wherein the transmitter comprises a wire having a length suitable for transmitting radio waves having a frequency which lies within the band 30 GHz-300 GHz.

5. The lithographic apparatus of claim 2, wherein the controller is configured to send a signal to the transmitter for transmission, the signal having a frequency which lies within the band 30 GHz-300 GHz. transmission, the signal having a frequency which lies within the band 30 GHz-300 GHz.

6. The lithographic apparatus of claim 2, wherein the controller is configured to send a signal to the transmitter for transmission which comprises a plurality of frequencies.

7. The lithographic apparatus of claim 2, wherein the controller is configured to send a signal to the transmitter for transmission which includes a modulation.

8.-11. (canceled)

12. The lithographic apparatus of claim 2, further comprising a plurality of antennas.

13. The lithographic apparatus of claim 12, wherein the analysis apparatus is configured to determine the location of damage to the filter based upon the phase of radio waves received by the antennas.

14. The lithographic apparatus of claim 2, further comprising a blocking structure provided around a perimeter of the filter, the blocking structure being configured to block radio waves which would otherwise pass around sides of the filter.

15. (canceled)

16. A filter damage detection apparatus, comprising:
an antenna configured to receive radio waves; and
an analysis apparatus configured to determine the presence of filter damage based upon the received radio waves.

17. The filter damage detection apparatus of claim 16, wherein the apparatus further comprises a transmitter configured to transmit radio waves.

18. A method of monitoring for damage of a filter, the method comprising:
receiving radio waves using an antenna; and
determining the presence of filter damage based upon the received radio waves.

19. The method of claim 18, wherein the method further comprises transmitting radio waves at an opposite side of the filter from the antenna.

20. The method of claim 18, wherein determining the presence of filter damage is performed by comparing the received radio waves with received background radio waves.
